(19) United States
(12) Patent Application Publication
(10) Pub. No.: US 2010/0060282 A1
(43) Pub. Date: Mar. 11, 2010

(54) THREE-DIMENSIONAL ASYMMETRIC TRANSVERSE GRADIENT COILS

(75) Inventors: Shmaryu M. SHVARTSMAN, Highland Heights, OH (US); Gordon D. DeMEESTER, Wickliffe, OH (US); Michael A. MORICH, Mentor, OH (US)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N. V., Eindhoven (NL)

(21) Appl. No.: 12/302,343

(22) PCT Filed: May 9, 2007
(86) PCT No.: PCT/US07/68522

§ 371 Date: Nov. 25, 2008

Related U.S. Application Data
(60) Provisional application No. 60/803,160, filed on May 25, 2006.

(51) Int. Cl. G01R 33/44

(52) U.S. Cl. 324/318

(57) ABSTRACT

A transverse magnetic field gradient coil includes a set of primary coil loops (62) defining an operative coil end (66) and a distal coil end (68). The set of primary coil loops are configured to generate a magnetic field gradient in a selected region asymmetrically disposed relatively closer to the operative coil end and relatively further from the distal coil end. A set of shield coil loops (64) are disposed outside the set of primary coil loops and are configured to substantially shield the set of primary coil loops. Two or more current jumps (70) are disposed at the distal end. Each current jump electrically connects an incomplete loop of the set of primary coil loops with an incomplete loop of the set of shield coil loops.

The present application relates to magnetic field gradient coils. It finds exemplary application in magnetic resonance imaging, and is described with example reference thereto. However, it finds more general application in magnetic resonance scanning applications including imaging, spectroscopy, and so forth, and in other applications employing magnetic field gradients.

Magnetic resonance scanners for medical imaging typically employ whole-body magnetic field gradient coils disposed in the scanner housing. Magnetic field gradient coils typically consist of an axial/longitudinal gradient coil and two sets of transverse gradient coils, each orthogonal to the others. Advantageously, such whole-body transverse magnetic field gradient coils can produce magnetic field gradients over a large volume. However, whole-body transverse magnetic field gradient coils have relatively large inductance and employ relatively large electrical currents compared to smaller-dimensioned gradient coils, and this leads to disadvantages compared with such smaller gradient coils such as lower gradient strength, lower slew rate, and substantial mechanical stressing and noise when changing the gradient.

When imaging is performed over a relatively small volume of interest, such as the head or a limb, the large-volume advantage of whole-body transverse magnetic field gradient coils is not necessary. Accordingly, it is known to substitute a local magnetic field gradient coil for the whole-body coil. The smaller volume gradient coil entails lower inductance and enables operation at lower electrical current compared with a whole-body gradient coil. Thus, local magnetic field gradient coils can achieve higher gradient strength, higher slew rate, and less mechanical stressing and noise. However, these advantages typically come at the cost of reduced magnetic field gradient uniformity due to the smaller coil size. Additionally, the local gradient coil is positioned relatively closer to the patient, which can lead to coil-patient interference, and reduces space for radio frequency coils that are used to excite and receive magnetic resonance signals. For example, in the case of a local gradient head coil, the shoulders of the patient may block or interfere with the patient end of the coil and limit access into the imaging region of the gradient coil. To allow for the shoulders, the gradient coil can be made short (e.g., extending only to the neck) which limits uniformity, or the coil can be made large enough to encompass the shoulders. If the coil is made larger to encompass the shoulders then this reduces one advantage of local gradients, namely the advantage of exposing a smaller portion of the patient to fields that can generate nerve stimulation during operation.

These problems are partially addressed by using an asymmetric coil, in which the region of highest magnetic field gradient uniformity (i.e., the imaging region) is asymmetrically disposed at the patient end of the local gradient coil but substantially centered on the magnet's imaging region. This enables the service end opposite the patient end to extend further out, providing a larger coil for improved gradient uniformity and manufacturability while having a short distance to the patient end of the coil to avoid impinging upon the shoulders of the patient. However, the larger coil volume of the asymmetric local coil leads to relatively higher inductance, higher operating current and attendant reduction in gradient strength and slew rate, increased mechanical stressing and noise. The extension of the service end of the coil also can be inconvenient for local coils that are intended to be selectively insertable and removable, or for local coils that are intended for mounting on the patient couch, or so forth, due to increased size and weight. Accordingly, existing asymmetric gradient coils retain an undesirable tradeoff between coil size and magnetic field gradient uniformity.

The present application discloses new and improved asymmetric magnetic field gradient coils which overcomes the above-referenced problems and others.

In accordance with one aspect, a transverse magnetic field gradient coil is disclosed. A set of primary coil loops define an operative coil end and a distal coil end. The set of primary coil loops are configured to generate a magnetic field gradient in a selected region asymmetrically disposed relatively closer to the operative coil end and relatively further from the distal coil end. A set of shield coil loops are disposed outside the set of primary coil loops and are configured to substantially shield the set of primary coil loops. Two or more current jumps are disposed at the distal end. Each current jump electrically connects an incomplete loop of the set of primary coil loops with an incomplete loop of the set of shield coil loops.

In accordance with another aspect, a magnetic resonance scanner is disclosed. A static magnet generates a static magnetic field in a selected region. A transverse magnetic field gradient coil as set forth in the preceding paragraph is disposed asymmetrically respective to the selected region and is arranged to generate a magnetic field gradient in the selected region. A radio frequency excitation system is configured to excite magnetic resonance in the selected region.

In accordance with another aspect, a method is disclosed for generating a transverse magnetic field gradient. A primary current density spatial distribution is generated surrounding a cylindrical coil volume defining an axis. The primary current density spatial distribution produces a magnetic field gradient in a selected region asymmetrically positioned in the cylindrical coil volume relatively closer to an operational end of the cylindrical coil volume and relatively further from a distal end of the cylindrical coil volume. A shield current density spatial distribution is generated outside of the generated primary current density spatial distribution that substantially shields the primary current density spatial distribution. The primary and shield current density spatial distributions are connected at multiple spaced-apart points or over a spatially extended region at the distal end of the cylindrical coil volume. The connecting causes an axial current density component of the generated primary current density spatial distribution to be non-zero at the distal end of the cylindrical coil volume. In some embodiments, the generating operations include flowing a drive current through primary coil loops and shield coil loops disposed around the cylindrical coil volume, and the connecting includes connecting selected primary coil loops and selected shield coil loops by spaced-apart jump conductors disposed at the distal end of the cylindrical coil volume.

One advantage resides in an asymmetric transverse magnetic field gradient coil with improved gradient uniformity.

Another advantage resides in providing an asymmetric transverse magnetic field gradient coil with larger magnetic field gradient strength, or in enabling a design tradeoff between lower stored magnetic energy and higher efficiency or improved linearity/uniformity.

Another advantage resides in providing an asymmetric transverse magnetic field gradient coil with larger slew rate due to lower stored magnetic energy/inductance.

Another advantage resides in providing an asymmetric transverse magnetic field gradient coil that produces less gradient coil bending force.

Another advantage resides in providing a more compact asymmetric transverse magnetic field gradient coil.

Still further advantages of the present invention will be appreciated to those of ordinary skill in the art upon reading and understand the following detailed description.

The invention may take form in various components and arrangements of components, and in various steps and arrangements of steps. The drawings are only for purposes of illustrating the preferred embodiments and are not to be construed as limiting the invention.

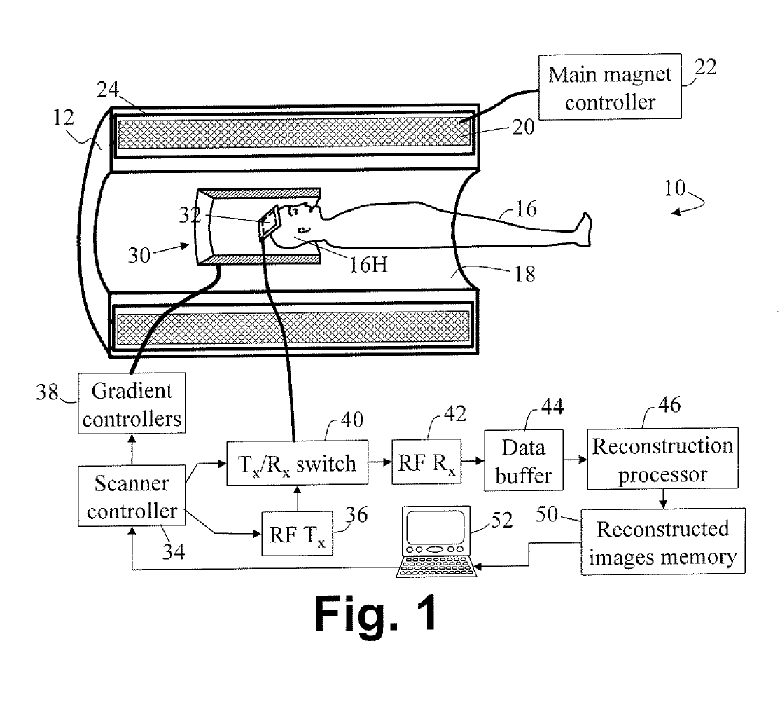

FIG. 1 diagrammatically shows a magnetic resonance scanner. The scanner is shown in partial cutaway to reveal a magnetic field gradient coil assembly disposed in the bore that includes at least one three-dimensional (3D) transverse magnetic field gradient coil set. The magnetic field gradient coil assembly is shown in partial cutaway to reveal a radio frequency coil disposed in the magnetic field gradient coil assembly.

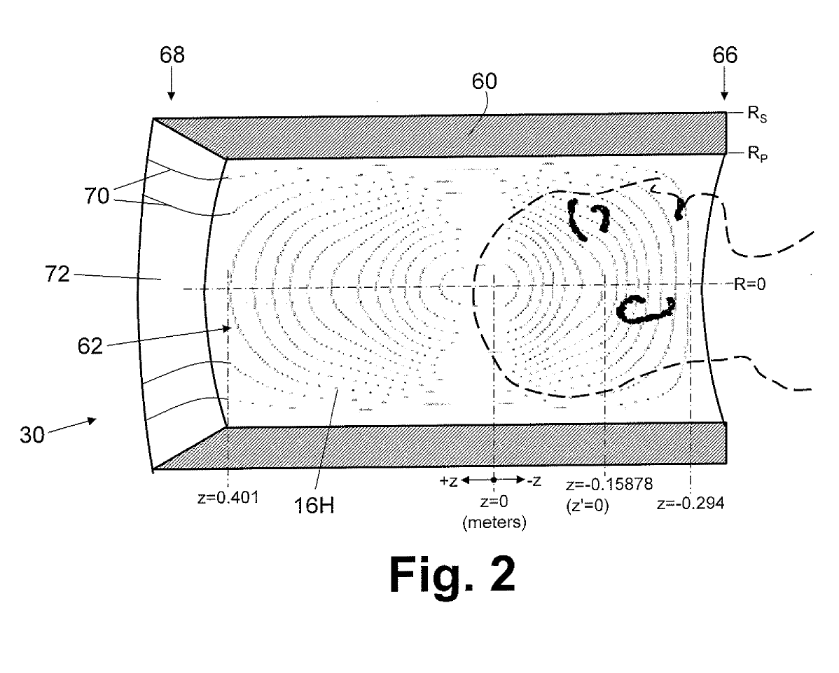

FIG. 2 diagrammatically shows the partial cutaway view of the 3D magnetic field gradient coil assembly of FIG. 1 in greater detail, including one fingerprint of the primary coil loops set and current jumps between the primary and shield coil loops sets.

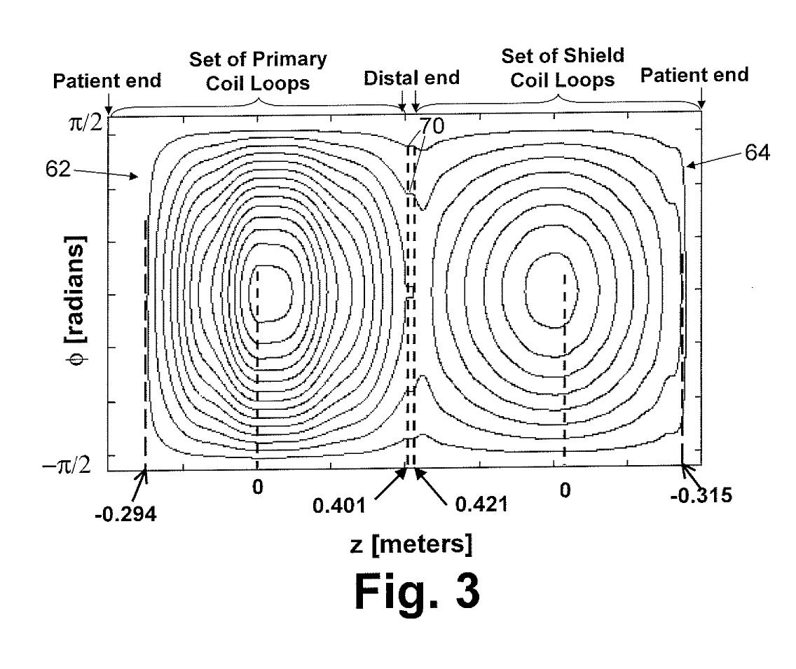

FIG. 3 diagrammatically shows the unfolded primary and shield current loops of one of two fingerprint sets of the 3D magnetic field gradient coil assembly of FIGS. 1 and 2. Two such sets placed on opposite sides of the cylindrical surface form a complete transverse gradient coil. The opposite transverse coil pair is not shown. Current jumps between primary and shield current loops are shown at the distal end, marked near the center of FIG. 3.

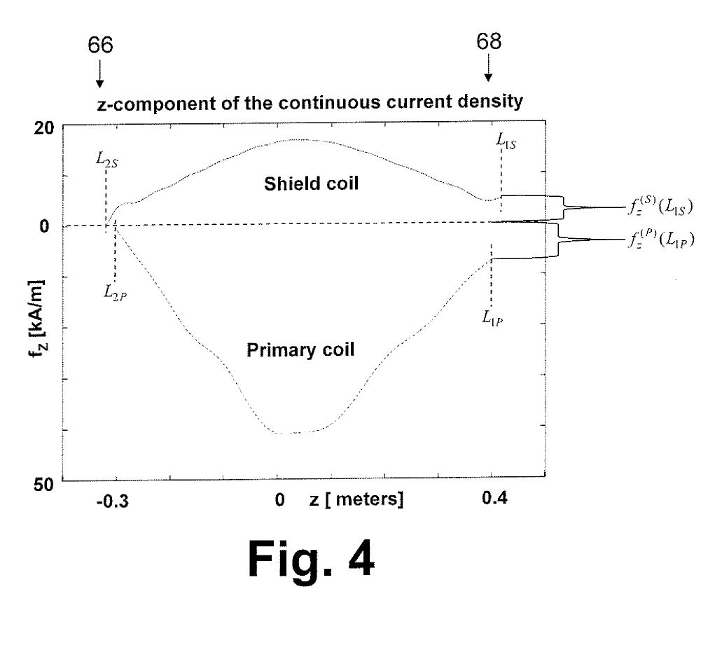

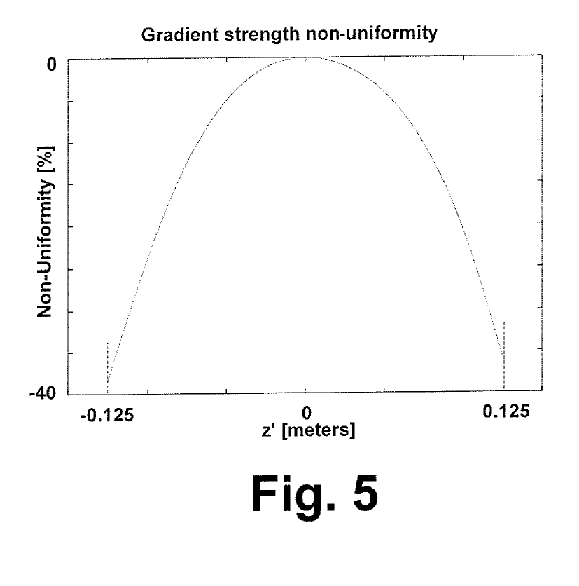

FIG. 4 plots simulated z-components of the continuous current density of the 3D magnetic field gradient coil assembly of FIGS. 1-3. FIG. 5 plots simulated gradient strength non-uniformity of the 3D magnetic field gradient coil assembly of FIGS. 1-3. The graph in FIG. 5 is centered on the imaging region center (z′=0, z=−158.78 mm) of the gradient coil.

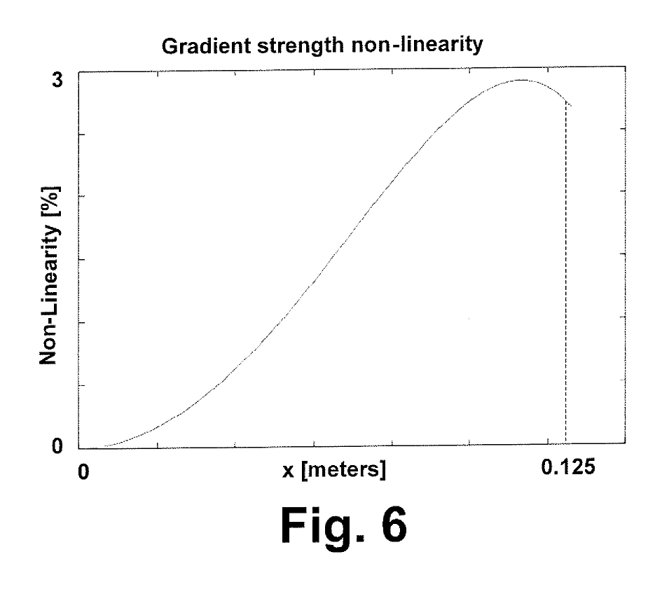

FIG. 6 plots simulated gradient strength non-linearity of the 3D magnetic field gradient coil assembly of FIGS. 1-3. The x-axis in FIG. 6 is orthogonal to the z-axis and is aligned with φ=0 degrees. The x-axis is the left-right axis (shoulder direction).

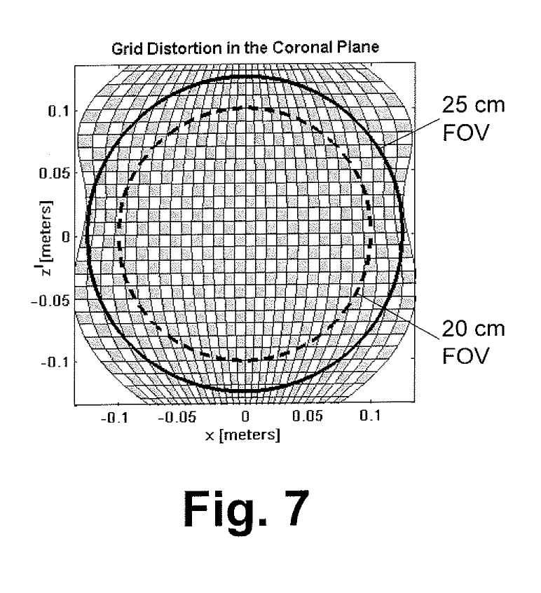

FIG. 7 plots grid distortion in the coronal (x-z′) plane for the 3D magnetic field gradient coil assembly of FIGS. 1-3. The distortion grid in FIG. 7 is centered on the imaging region center (z′=0, z=−158.78 mm) of the gradient coil.

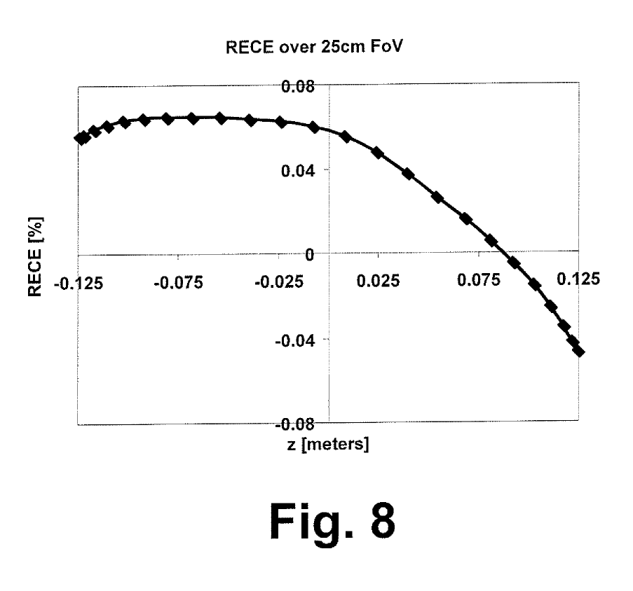

FIG. 8 plots residual eddy current effect (RECE) for the 3D magnetic field gradient coil assembly of FIGS. 1-3, where the eddy currents are generated on the surface of a surrounding cylindrical cold shield.

With reference to FIG. 1, a magnetic resonance scanner 10 includes a scanner housing 12 (shown in diagrammatic cutaway in FIG. 1) in which a patient 16 or other subject is at least partially disposed. Although described with reference to a bore-type scanner, it is to be appreciated that the scanner could also be an open-magnet scanner or other type of magnetic resonance scanner. A protective insulating bore liner 18 of the scanner housing 12 optionally lines a generally cylindrical bore or opening of the scanner housing 12 inside of which the subject 16 is disposed. A main magnet 20 disposed in the scanner housing 12 is controlled by a main magnet controller 22 to generate a static (B₀) magnetic field in at least a scanning region including at least a portion of the subject 16. Typically, the main magnet 20 is a persistent superconducting magnet surrounded by cryoshrouding 24. In some embodiments, the main magnet 20 generates a main magnetic field of at least about 0.2 Tesla, such as 0.23 Tesla, 1.0 Tesla, 1.5 Tesla, 3 Tesla, 7 Tesla, or so forth. A magnetic field gradient coil assembly 30 (shown in diagrammatic cutaway in FIGS. 1 and 2) is arranged in bore defined by the housing 12 to superimpose selected magnetic field gradients on the main magnetic field in at least a selected region such as an imaging region or a region in which magnetic resonance spectroscopy is to be performed. In FIG. 1, the selected region is an imaging region in which the head 16H of the subject 16 is disposed. Typically, the local magnetic field gradient coil assembly 30 includes sets of coil loops or windings for producing two transverse magnetic field gradients, such as x- and y-gradients, and one longitudinal gradient, such as a z-gradient. Optionally, one or more of these sets of coil loops or windings, such as the set of longitudinal magnetic field gradient loops or windings, may be disposed elsewhere, such as on a cylindrical former disposed on or in the scanner housing 12.

A radio frequency coil 32 is electromagnetically coupled with the head of the subject 16. The radio frequency coil 32 is a transmit/receive (T/R) coil that is selectably configured to be externally energized to excite magnetic resonance in the head of the subject 16, and to act as a receiver to receive magnetic resonance signals generated by the excitation. In other embodiments, separate transmit and receive radio frequency (RF) coils may be used. It is contemplated to integrate the radio frequency coil within the magnetic field gradient coil assembly 30. It is also contemplated to use independent local and/or volume RF coils within the magnetic field gradient coil assembly 30.

In the example head imaging application illustrated in example FIG. 1, a scanner controller 34 operates a radio frequency transmitter 36 coupled with the T/R radio frequency coil 32 via transmit/receive switching circuitry 40 to excite magnetic resonance. The transmitter 36 applies a radio frequency pulse or packet of pulses at the magnetic resonance frequency to the coil 32 which generates a B₁ field at the magnetic resonance frequency at least in a selected region of the head of the patient 16. Optionally, a slice- or slab-selective magnetic field gradient is applied by the magnetic field gradient coil assembly 30, operated by magnetic field gradient controllers 38 during the radio frequency excitation, so as to limit the region of excitation to a selected slice or slab. During the receive phase of the magnetic resonance imaging sequence, the scanner controller 34 causes the transmit/receive switching circuitry 40 to switch over to receive mode, and magnetic resonance signals emanating from the head of the subject 16 are detected by the T/R radio frequency coil 32 and processed by a radio frequency receiver 42 to generate magnetic resonance samples that are stored in a data buffer 44 or other memory. Optionally, the scanner controller 34 causes the gradient controllers 38 and magnetic field gradient coil assembly 30 to apply spatial encoding magnetic field gradients, such as one or more phase-encoding magnetic field gradients applied in the interval between magnetic resonance excitation and readout, or one or more frequency-encoding magnetic field gradients applied during readout, or so forth. A reconstruction processor 46 employs a Fourier Transform reconstruction algorithm, filtered backprojection reconstruction algorithm, or other reconstruction algorithm comporting with the spatial encoding implemented by the magnetic field gradient coil assembly 30, to reconstruct the magnetic resonance samples stored in the data buffer 44 into a reconstructed image of the head or selected slice or other portion thereof. The reconstructed images are stored in a reconstructed images memory 50, displayed by a user interface 52, transmitted to a workstation, desktop computer, or other device via a hospital network or the Internet, printed by a printing device, or otherwise utilized. In the example illustrated in FIG. 1, the user interface 52 also enables a radiologist, physician, or other operator to interface with the scanner controller 34 to control the scanner 10 to perform selected imaging, spectroscopy, or other useful sequences; in other embodiments, separate control and image display computers or devices may be provided.

With reference to FIGS. 2 and 3, the local magnetic field gradient coil assembly 30 is described in greater detail. FIG. 2 shows an enlarged cutaway view of the magnetic field gradient coil assembly 30 including a diagrammatic view of one-half of the primary coil loops or windings, while FIG. 3 diagrammatically shows an unfolded representation of one-half of the current loops or windings. In the following, a single set of transverse coil loops or windings is described, which, with an opposite pair, is suitable for generating an x-gradient or a y-gradient—however, it is to be understood that the magnetic field gradient coil assembly 30 typically includes two such sets of coil loops or windings, separated from each other by a dielectric layer or other insulation and generally rotated 90° from one another, to selectively produce both x- and y-gradients, and it is to be further understood that the magnetic field gradient coil assembly 30 optionally includes other components such as a set of longitudinal coil loops or windings, an integral radio frequency coil and/or radio frequency shield, or so forth.

The illustrated magnetic field gradient coil assembly 30 includes a generally cylindrical dielectric former 60 with a circular cross-section of constant cross-section along the length of the cylindrical former 60. Formers with elliptical, rectangular, or otherwise-shaped cross-sections are also contemplated. It is further contemplated for the former to deviate from cylindrical in other ways, such as by having a conical shape. In some embodiments, the former 60 has a large enough diameter to receive the top portion of the shoulders of the patient. A set of primary coil loops or windings 62 is disposed on or near an inner surface of the cylindrical former 60. FIGS. 2 and 3 each show a fingerprint spanning an azimuthal range of about 180°. The set of primary coil loops includes a second, symmetrical fingerprint that is not visible in FIGS. 2 and 3, disposed on or near the inner surface of the cylindrical former 60 spanning substantially the remaining 180° azimuthal range. That is, the full set of primary coil loops or windings includes two facing fingerprints each comprising a plurality of loops or windings.

A set of shield coil loops or windings 64 (hidden in FIG. 2 but shown in FIG. 3) is disposed on or near the outer surface of the dielectric former 60 overlapping and shielding the set of primary coil loops or windings 62. In the example of FIGS. 2 and 3, the two fingerprints of the set of primary coil loops or windings 62 have a corresponding two fingerprints of the set of shield coil loops or windings 64, only one shield windings fingerprint being visible in FIG. 3. Thus, the full set of shield coil loops includes two fingerprints each comprising a plurality of loops or windings.

The subject of interest, namely the head 16H in FIGS. 1 and 2, is aligned with the region of substantially uniform gradient field, i.e., an imaging region, which is asymmetrically disposed relatively closer to a patient or operative coil end 66 and relatively further from a distal coil end 68. That is, the magnetic field gradient coil assembly 30 is an asymmetric coil assembly. The “eye” of the fingerprint current patterns of the primary and shield windings 62, 64 approximately corresponds with the region of maximum Z-directed current density and substantially zero azimuthal-directed current density. The isocenter of the imaging region is denoted by z′ in FIG. 2, and is positioned at z=−158.78 mm meters respective to the eye of the fingerprint current patterns. That is, the z′ coordinate system is respective to the imaging region center, and is offset from the z coordinate system of the windings 62, 64 such that z′˜z+158.78 mm. The center of the imaging region (z′=0) is asymmetrically disposed relatively closer to the patient or operative coil end 66 and relatively further from the distal coil end 68, generally located between the physical operative end of the coil and the eye of the primary fingerprint current pattern. The asymmetric arrangement is advantageous in applications, such as head imaging, in which the selected region of interest for imaging, spectroscopy, or other examination is located close to a spatial blockage (i.e., the shoulders in the case of head imaging).

Selected loops of the set of primary coil loops or windings 62 are connected with selected loops of the set of shield coil loops or windings 64 by current jumps 70 disposed at the distal coil end 68. Each current jump 70 electrically connects an incomplete (that is, non-closed) loop of the set of primary coil loops 62 with an incomplete loop of the set of shield coil loops 64. The jumps 70 are different from the current feed locations at which the coil sets 62, 64 are connected to the gradient controllers or amplifiers 38. In the case of a jump 70, current flows through a loop of the set of primary coil loops 62, which is typically less than a full closed loop, across one of the jumps 70, through a loop of the set of shield coil loops 64, which again is typically less than a full closed loop, and back through a second one of the jumps 70 to return to the primary coils set (or vice versa). As will be discussed, the jumps 70 substantially affect the current distribution and resultant generated magnetic field gradient, for example by enabling the axial or z-component of the current to be non-zero at the distal coil end 68, and reduce the overall coil inductance and so forth. In contrast, the current feed locations connect the set of coils 62, 64 with the opposite set of coils and with the gradient controllers or amplifiers 38. Current feeds are typically associated with otherwise complete or closed coil loop patterns. In some cases current feeds may also provide a series connection of the set of primary coils 62 as a whole with the set of shield coils 64 as a whole. Such series current feeds or interconnects do not substantially change the current distribution and resultant generated magnetic field gradient, but merely provides a convenient configuration for driving the primary and shield coils sets 62, 64, in series using a single drive current. Typically, current feeds carrying current in opposite directions are placed close together in magnetic field cancelled pairs, or are placed at opposite ends of the coil, to substantially cancel or reduce the impact of the currents that flow in the current feeds. In contrast, the current jumps 70 are typically not placed close together so as to cancel.

In the illustrated magnetic field gradient coil assembly 30, the area of the set of shield coil loops or windings 64 is slightly larger than the area of the set of primary coil loops or windings 62, and this area difference is accommodated in part by having a flared or conical surface 72 (best shown, and labeled, in FIG. 2) at the distal coil end 68. The flared or conical surface 72 flares outwardly from the inner radius of the cylindrical former 60 to the outer surface of the cylindrical former 60, and the jumps 70 are typically flared jumps that lie on or parallel with the flared surface 72. In other embodiments, however, a straight or right-angled surface may connect the inner and outer surfaces of the former, and the jumps are suitably radial jumps that lie on the straight or right-angled surface. It is also contemplated to employ radial jumps in conjunction with the flared connecting surface 72, for example by passing the jumps through radial passthrough holes drilled through the dielectric former or embedded within an appropriate epoxy potting compound if the primary coils are located on the outside of a primary dielectric former. A pair of jumps, which are typically although not necessarily azimuthally separated from each other, connect the same loop of the set of primary coil loops 62 with the same loop of the set of shield coil loops 64, so as to define an electrical conduction path passing through the primary loop, the first jump, the shield loop, and the second jump to arrive back on the primary side of the former 60.

The jumps 70 provide certain advantages. The overall inductance of the windings 62, 64 is reduced. For example, the set of primary coil loops 62 and the set of shield coil loops 64 are typically configured to be driven by a single drive current, for example by connecting the primary and shield loop sets 62, 64 in series by interconnects at the compass positions. In such a series-interconnect arrangement, the current jumps 70 substantially reduce an inductance of the transverse magnetic field gradient coil seen by the drive current, which reduces the stored energy. Moreover, the current jumps 70 also allow the axial or z-component of the current density to be non-zero at the distal end 68 of the coil assembly 30. This enables a reduction of the packing density and associated heat deposition of loops at the distal end 68. In other words, by providing a nonzero axial or z-component to the current density, the overall current density and coil heating at the distal end 68 can be reduced while maintaining the desired coil operational characteristics such as asymmetric imaging volume size and uniformity.

These advantages are further set forth using examples as follows. In the following, the illustrated magnetic field gradient coil assembly 30 is designed for use in a magnetic resonance scanner operating at a static (B₀) field of 7 Tesla. The coil windings and jumps 62, 64, 70 define a three-dimensional (3D) gradient coil design that allows multiple connections, i.e. jumps 70, between loops of the primary and shield coil sets 62, 64 so some current paths jump or cross over between the primary and shield coil sets 62, 64. One way of viewing the effect of the jumps 70 is that, at the distal end 68 of the coil assembly 30, some of the outer loops are partly on a mathematical primary surface defined by the primary loops set 62 (for example, the mathematical primary surface corresponds to the inner surface of the former 60 when the primary coil loops 62 are disposed on that inner surface), partly on a mathematical shield surface defined by the shield loops set 64 (for example, the mathematical shield surface corresponds to the outer surface of the former 60 when the shield coil loops 64 are disposed on that outer surface), and partly on a mathematical connecting surface that connects the mathematical primary and shield surfaces (for example, the mathematical connecting surface corresponds to the flared surface 72 at the distal end 68 when the jumps 70 are disposed on that surface). In the illustrated embodiment, the mathematical primary and shield surfaces are the coaxial inner and outer cylindrical surfaces of the former 60; however, the mathematical surfaces may be non-cylindrical (for example, if the supporting dielectric former is non-cylindrical), and may be different from the physical surfaces of the former (for example, if the windings are embedded inside the dielectric former, or are offset from the surface of the former by standoffs, or if there are two separate formers for primary and shield, or so forth). An advantage of 3D coils over a shielded set of coils without the current jumps 70 is more efficient magnetic field generation per ampere of current.

In the example for a 7 Tesla field, the radius of the inner surface of the former 60 (corresponding in this embodiment to the mathematical primary surface of the primary coils set 62) is Rₚ=0.191 meters, while the radius of the outer surface of the former 60 (corresponding in this embodiment to the mathematical shield surface of the shield coils set 64) is R_{S}=0.269 meters, and the overall length is 0.77 meters. The Field-of-View (FoV), or useful imaging volume, is a sphere of radius 125 millimeters and diameter 250 millimeters. The patient access, defined as the distance from the shoulder of the patient 16 to the isocenter of the FoV, is less than or about 175 millimeters. The desired achievable gradient strength at the isocenter of the FoV is at least 60 mT/m.

FIG. 4 shows a plot of the z-component of the continuous current density as a function of axial or z-position for the example asymmetric gradient coil designed for operation at 7 Tesla. The layout of the current paths 62, 64, 70 (shown for example in FIG. 3) can be determined using various techniques, such as using parameterized electromagnetic simulators. The effect of the jumps 70 on the z-component of the current density is suitably described by the continuity equation for the continuous current density, which gives the following boundary condition at the distal end 68:

$${f}_{z}^{( S )} ( {L}_{1 S} ) = - \frac{{R}_{P}}{{R}_{S}} {f}_{z}^{( P )} ( {L}_{1 P} ) , \qquad ( 1 )$$

where f_{z}^{(P)}(z) and f_{z}^{(S)}(z) are the z-components of the continuous current densities as a function of axial or z-position on the primary and the shield coil sets 62, 64, respectively, and L_{1P} and L_{1S} are the axial or z-coordinate end positions of the primary and shield coil sets 62, 64, respectively, at the distal end 68 of the coil assembly 30. Also labeled in FIG. 4 are L_{2P} and L_{2S} which are the respective end positions of the primary and shield coil sets 62, 64 at the operative or patient coil end 66. As seen in FIG. 4, the z-components of the continuous current densities on the primary and the shield coil are equal to zero at the patient end 66 (i.e., at L_{2P} and L_{2S}), because there are no current jumps between primary and shield at the patient end 66. On the other hand, as further seen in FIG. 4, the z-components of the continuous current densities f_{z}^{(P)}(L_{1P}) and f_{z}^{(S)}(L_{1S}) at the distal end 68 (i.e., at L_{1P} and L_{1S}) are non-zero, which is made possible by the current conducted by the current jumps 70.

In a suitable approach for designing the jumps 70, the z-components of the continuous current densities f_{z}^{(P)}(L_{1P}) and f_{z}^{(S)}(L_{1S}) at the distal end 68 are optimiz during optimization of the current densities to minimize the stored energy, subject further to the constraint of Equation (1). Once the current densities are optimized, including optimized values for f_{z}^{(P)}(L_{1P}) and f_{z}^{(S)}(L_{1S}), the current densities are discretized into a finite number of current paths or loops, including a suitable number of jumps 70 to provide the appropriate z-component current at L_{1P} and L_{1S}. In the set of discretized current paths shown in FIG. 3, there are fourteen loops on the primary coil set 62, eight loops on the shield coil set 64, and the outer two primary and shield loops are shared by the jumps 70. In this example design, the angle of the flared surface 72 (and hence the angle of the current jumps 70 that in this embodiment lie on the flared surface 72) is 75.62° relative to the Z-axis. The patient access of the coil assembly 30 in this example is 171 millimeters, which defines the distance from the edge of the longest coil (the shield coil set 64 in this case) to the isocenter of the FoV. The current that is needed to generate 60 mT/m gradient strength at the isocenter of the FoV is 578 amperes. The center of imaging is located at Z_{SS}=−158.78 millimeters (z′=0), relative to the z=0 position defined for the current density distribution. Typically, the center of the imaging volume is chosen to coincide with the “sweet spot”, i.e., the region of highest static (B₀) field uniformity, for the main magnet 20.

With reference to FIGS. 5 and 6, gradient strength non-uniformity and gradient strength non-linearity over 25 cm FoV of the shifted coil are shown, respectively. Note that FIGS. 5 and 6 are referenced to the z′ coordinate system of the imaging center, where z′=z+158.78 mm. That is, the imaging center at z′=0 is 158.78 mm from the z=0 isocenter labeled in FIGS. 2-4.

With reference to FIG. 7, gradient distortion of the pixel grid in the central coronal plane is illustrated. Each undistorted pixel is 5 mm×5 mm in size. In FIG. 7, the solid line denotes the circular boundary of a 25 cm FoV, while the dashed line denotes the circular boundary of a smaller 20 cm FoV. FIG. 7 is plotted in the x-z′ coordinate system, so that the center of the gradient distortion plot of FIG. 7 is aligned with the imaging center at z′=0.

With reference to FIG. 8, estimated residual eddy current effect (RECE) over the surface of the aforementioned 25 cm FoV is shown. The RECE is estimated for eddy current generated on the surface of a surrounding cylindrical cold shield whose radius is R_{CS}=0.475 m. The estimated residual eddy current is less than or about 0.07%. More generally, for various quantitative designs it is expected that asymmetric magnetic field gradient coils with the geometry including the shield windings set 64 and current jumps 70 at the distal end should be operative to reduce the residual eddy current effect (RECE) of the set of primary coil loops 62 to less than or about 1%, and should be further operative to reduce the stored energy or inductance by 15-20% compared with a similar coil employing primary and shield coil sets but no current jumps.

The coil assembly 30 described with reference to FIGS. 2-8 includes four current jumps per set of primary/shield fingerprints (as seen in FIG. 3), or eight current jumps total since there are two opposing sets of primary/shield fingerprints in the asymmetric coil. As seen in FIG. 3, a pair of jumps connects a primary coil loop and a corresponding shield coil loop. Typically, there are fewer shield coil loops than primary coil loops. In some embodiments, it is contemplated to have enough jumps to connect every shield coil loop with a primary coil loop, with some inner primary coil loops remaining unconnected with any shield coil loops. More typically, there will also be some inner shield coil loops that are unconnected with any primary coil loops. This is the situation shown in FIG. 3, where the set of primary coil loops 62 includes 14 loops of which twelve are unconnected with any shield coil loops, and the set of shield coil loop 64 includes 8 loops of which six are unconnected with any primary coil loops.

As another example, Table I shows simulated parameters for an optimized 7 Tesla 3D asymmetric transverse magnetic field gradient coil having six jumps per fingerprint (twelve jumps total, since there are two opposing fingerprints), compared with an equivalent optimized 7 Tesla two-dimensional (2D) topology having no jumps between primary and shield loops.

TABLE I
Characteristics of a transverse gradient coil having 6 jumps/fingerprint

| Property | 3D topology | 2D topology |
|---|---|---|
| R_{P} [mm] | 191.0 | 191.0 |
| R_{S} [mm] | 269.0 | 269.0 |
| Number of loops on half of the primary | 14 | 14 |
| coil | | |
| Number of loops on half of the | 9 | 8 |
| shield coil | | |
| Number of jumps on half of the coil | 6 | 0 |
| Electrical length [mm] (primary/shield) | 709.34/745.88 | 706.03/741.55 |
| Patient access [mm] | 171.1 | 172.2 |
| Field-of-View [cm] | 25.0 | 25.0 |
| Conductor thickness [mm] | 5.0 | 5.0 |
| Conductor width [mm] (Primary/Shield) | 14.0/10.0 | 13.0/9.0 |
| Inductance [μH] | 94.87 | 103.57 |
| Stored energy [J] at G = 60 mT/m | 15.83 | 19.5 |
| Resistance [mΩ] | 18.19 | 19.89 |
| Gradient strength [mT/m] | 60.0 | 60.0 |
| Sensitivity [μT/m/A] | 103.85 | 97.75 |
| Range of RECE over 25 cm FoV | 0.111 | 0.247 |
| Gradient strength non-uniformity | | |
| over 25 cm FoV | | |
| z = −0.125 m and x = 0 | −38.52% | −38.28% |
| z = +0.125 m and x = 0 | −35.67% | −36.81% |
| Gradient strength non-linearity at | +2.83% | +2.66% |
| x = 0.125 m and z = 0 | | |
| Current required for 60 mT/m [A] | 578 | 614 |
| Power at 60 mT/m [kW] | 6.1 | 7.5 |
| Slew Rate at 600 V [T/m/s] | 605 | 580 |

The stored energy at 60 mT/m for the 3D design vs. the 2D design is 15.83 J vs. 19.5 J, which is a 19% reduction in energy attributable to the jumps. When the number of current jumps between the primary coil and the shield coil increases (number of loops that coil was discretized with on the primary and shield coil increases) the differences between the properties of 3D topology and 2D topology becomes more profound. It is therefore advantageous to use jumps for shielded gradient coils with many turns/loops where sensitivity is being maximized. In the 3D coil of Table I, two of the six jumps (i.e., one pair of jumps) are sufficiently close to each other (that is, have small azimuthal separation) so that the z-component of current conducted by those two jumps substantially cancel. Thus, the 3D coil of Table I, although referred to as a six jump coil, has certain attributes of a four-jump coil.

More generally, the jumps are advantageously azimuthally spaced apart or separated from one another so that the z-component of the current in the jumps does not cancel out. In other words, the azimuthally spaced-apart current jumps 70 define an azimuthal distribution of current density transfer at the distal end between the set of primary coils 62 and the set of shield coils 64. Typically, jumps are disposed only at the distal end 68, with no jumps disposed at the operative or patient end 66. Locating jumps at the patient end 66 is expected to have certain disadvantages such as coupling with the patent's shoulders (in the case of a head coil), reduced gradient strength per unit ampere, or reduced uniformity in the FoV which is asymmetrically disposed relatively closer to the patient end 66 and relatively further from the distal end 68. However, it is also contemplated to include a small number of jumps at the patient end, for example to relieve excessive pileup or crowding of current loops at the patient end when such current density issues arise in a specific gradient coil design. In this case, the number of current jumps at each end may not be the same. Each pair of current jumps connects a primary coil loop of the set of primary coil loops 62 with a shield coil loop of the set of shield coil loops 64. Each such pair of current jumps typically connects a different pair of primary and shield coil loops. So, two current jumps are employed to connect a single (typically outermost) pair of primary and shield loops of a fingerprint pattern; four current jumps are employed to connect two (typically outermost) pairs of primary and shield loops of a fingerprint pattern (the configuration shown in example FIG. 3); six current jumps are employed to connect three (typically outermost) pairs of primary and shield loops of a fingerprint pattern; and so forth.

The net force exerted on the gradient coil in the presence of a large whole body access 7 T magnet at G=60 mT/m is negligible as the magnet's field is reasonably uniform over the extent of the coil. This is true for both the 3D and 2D topologies of Table I. The net torque (about the center of mass of the coil) exerted on the gradient coil in the presence of a large whole body access 7 T magnet at G=60 mT/m is, without any special considerations, non-zero for both the 3D and 2D topology. The net torque can be made small, or practically zero, by slight adjustment of the innermost loops on the shield coil that do not have connections with the loops on the primary coil. This adjustment does not have a significant impact on the coil characteristics.

Simulated parameters for another example design with ten jumps/fingerprint (twenty jumps total) and greater non-linearity is set forth in Table II. In this case the current distribution is discretized with 16 loops on the primary, 10 loops on the shield, and five shared loops per fingerprint (effected by five pairs of jumps per fingerprint, i.e. ten total jumps per fingerprint).

TABLE II
Characteristics of the transverse gradient coil having
5 jumps/fingerprint

| Property | 3D topology | 2D topology |
|---|---|---|
| R_{P} [mm] | 191.0 | 191.0 |
| R_{S} [mm] | 269.0 | 269.0 |
| Number of loops on half of the | 16 | 15 |
| primary coil | | |
| Number of loops on half of the shield | 10 | 8 |
| coil | | |
| Number of jumps on half of the coil | 10 | 0 |
| Electrical length [mm] | 659.8/694.5 | 668.95/709.4 |
| (primary/shield) | | |
| Patient access [mm] | 165 | 166 |
| Field-of-View [cm] | 25.0 | 25.0 |
| Conductor thickness [mm] | 5.0 | 5.0 |
| Conductor width [mm] | 14.9/8.6 | 13.10/9.01 |
| (Primary/Shield) | | |
| Inductance [μH] | 85.42 | 97.58 |
| Stored energy [J] at G = 60 mT/m | 11.47 | 13.84 |
| Resistance [mΩ] | 19.00 | 20.00 |
| Gradient strength [mT/m] | 60.0 | 60.0 |
| Sensitivity [μT/m/A] | 115.79 | 112.65 |
| Range of RECE over 25 cm FoV | 0.211% | 0.07% |
| Gradient strength non-uniformity over | | |
| 25 cm FoV | | |
| z = −0.125 m and x = 0 | −42.52% | −41.83% |
| z = +0.125 m and x = 0 | −43.7% | −43.56% |
| Gradient strength non-linearity at | +4.97% | 4.46% |
| x = 0.125 m and z = 0 | | |
| Current required for G = 60.0 mT/m [A] | 518.18 | 532.62 |
| Dissipated power at 60 mT/m [kW] | 5.10 | 5.69 |
| Slew rate at 60 mT/m and 600 V | 710.7 | 614.8 |
| (including filters and cables) | | |

Comparing Table II with Table I, it is seen that the increased number of loops improves sensitivity, while the 3D topology reduces inductance compared with the 2D topology, and also reduces dissipated power. The stored energy at 60 mT/m for the 3D design vs. the 2D design is 11.47 J vs. 13.84 J, a 17% reduction in energy.

The invention has been described with reference to the preferred embodiments. Modifications and alterations may occur to others upon reading and understanding the preceding detailed description. It is intended that the invention be constructed as including all such modifications and alterations insofar as they come within the scope of the appended claims or the equivalents thereof.

1. A transverse magnetic field gradient coil comprising:
a set of primary coil loops defining an operative coil end and a distal coil end, the set of primary coil loops configured to generate a magnetic field gradient in a selected region asymmetrically disposed relatively closer to the operative coil end and relatively further from the distal coil end;
a set of shield coil loops disposed outside the set of primary coil loops and configured to substantially shield the set of primary coil loops; and
two or more current jumps disposed at the distal end, each current jump electrically connecting an incomplete loop of the set of primary coil loops with an incomplete loop of the set of shield coil loops.

2. The transverse magnetic field gradient coil as set forth in claim 1, wherein there are no current jumps disposed at the operative end of the set of primary coil loops.

3. The transverse magnetic field gradient coil as set forth in claim 1, wherein the two or more jumps include at least four current jumps.

4. The transverse magnetic field gradient coil as set forth in claim 1, wherein the set of primary coil loops and the set of shield coil loops define respective coaxial mathematical primary and shield cylindrical surfaces.

5. The transverse magnetic field gradient coil as set forth in claim 4, wherein the respective coaxial mathematical primary and shield cylindrical surfaces have substantially circular cross-sections at respective primary and shield coil radii, the shield coil radius being larger than the primary coil radius.

6. The transverse magnetic field gradient coil as set forth in claim 4, wherein the two or more current jumps include two or more pairs of current jumps, the current jumps of each pair of current jumps connecting corresponding incomplete loops of the set of primary coil loops and the set of shield coil loops such that current flows directly from one of the corresponding loops to the other through a jump.

7. The transverse magnetic field gradient coil as set forth in claim 4, further comprising:
a generally cylindrical dielectric former having an inner surface at about the mathematical primary cylindrical surface and an outer cylindrical surface at about the mathematical shield cylindrical surface, the dielectric former supporting the set of primary coil loops and the set of shield coil loops.

8. The transverse magnetic field gradient coil as set forth in claim 7, wherein the generally cylindrical dielectric former has a flared connecting surface disposed at the distal end connecting the inner and outer cylindrical surfaces, and the current jumps are disposed on the flared connecting surface.

9. The transverse magnetic field gradient coil as set forth in claim 4, wherein the set of primary coil loops define two fingerprint patterns disposed on opposite sides of the mathematical primary cylindrical surface, the set of shield coil loops define two fingerprint patterns shielding the respective two primary coil fingerprint patterns.

10. The transverse magnetic field gradient coil as set forth in claim 4, wherein the set of shield coil loops together with the current jumps are operative to reduce the residual eddy current effect of the set of primary coil loops to less than or about 1%.

11. The transverse magnetic field gradient coil as set forth in claim 1, wherein the two or more current jumps include two or more pairs of current jumps, each pair of current jumps connecting an incomplete primary coil loop of the set of primary coil loops with an incomplete shield coil loop of the set of shield coil loops, each pair of current jumps connecting a different pair of incomplete primary and shield coil loops.

12. The transverse magnetic field gradient coil as set forth in claim 1, wherein the set of primary coil loops define two fingerprint patterns disposed on opposite sides of the selected region, and the set of shield coil loops define two fingerprint patterns shielding the respective two primary coil fingerprint patterns.

13. The transverse magnetic field gradient coil as set forth in claim 1, wherein the set of primary coil loops include at least one loop that is not electrically connected with any loop of the set of shield coil loops by a current jump.

14. The transverse magnetic field gradient coil as set forth in claim 13, wherein the set of shield coil loops include at least one loop that is not electrically connected with any loop of the set of primary coil loops by a current jump.

15. The transverse magnetic field gradient coil as set forth in claim 1, wherein the set of shield coil loops together with the current jumps are operative to reduce the residual eddy current effect of the set of primary coil loops to less than or about 1%.

16. The transverse magnetic field gradient coil as set forth in claim 1, wherein the set of primary coil loops and the set of shield coil loops are configured to be driven in series by a single drive current, and the two or more current jumps substantially reduce an inductance of the transverse magnetic field gradient coil seen by said drive current.

17. The transverse magnetic field gradient coil as set forth in claim 1, wherein the set of primary coil loops includes at least some complete primary loops and at least one incomplete primary loop and the set of shield coil loops includes at least one incomplete shield loop corresponding with the at least one incomplete primary loop, and the two or more current jumps include a pair of current jumps connecting the ends of each corresponding pair of incomplete primary and incomplete shield loops.

18. The transverse magnetic field gradient coil as set forth in claim 17, wherein the set of shield coil loops further includes at least one complete shield loop.

19. The transverse magnetic field gradient coil as set forth in claim 17, wherein the set of primary coil loops includes at least two incomplete primary loops, the set of shield coil loops includes at least two incomplete shield loops, and the two or more current jumps disposed at the distal end include four or more current jumps disposed at the distal end.

20. A magnetic resonance scanner comprising:
a static magnet generating a static magnetic field in a selected region;
a transverse magnetic field gradient coil as set forth in claim 1 disposed asymmetrically respective to the selected region and arranged to generate a magnetic field gradient in the selected region; and
a radio frequency excitation system configured to excite magnetic resonance in the selected region.

21. A method for generating a transverse magnetic field gradient, the method comprising:
generating a primary current density spatial distribution surrounding a cylindrical coil volume defining an axis, the primary current density spatial distribution producing a magnetic field gradient in a selected region asymmetrically positioned in the cylindrical coil volume relatively closer to an operational end of the cylindrical coil volume and relatively further from a distal end of the cylindrical coil volume;
generating a shield current density spatial distribution outside of the generated primary current density spatial distribution that substantially shields the primary current density spatial distribution; and
connecting the primary and shield current density spatial distributions at multiple spaced-apart points or over a spatially extended region at the distal end of the cylindrical coil volume, the connecting causing an axial current density component of the generated primary current density spatial distribution to be non-zero at the distal end of the cylindrical coil volume.

22. The method as set forth in claim 21, wherein the generating operations include flowing a drive current through primary coil loops and shield coil loops disposed around the cylindrical coil volume, and the connecting includes connecting selected primary coil loops and selected shield coil loops by spaced-apart jump conductors disposed at the distal end of the cylindrical coil volume such that current flows from one of the primary loops through one of the jumps into one of the shield loops and through a second of the jumps from the one of the shield loops to another primary loop.
